(19) United States
(12) Patent Application Publication
(10) Pub. No.: US 2026/0344236 A1
(43) Pub. Date: Oct. 29, 2026

(54) LIGHT EMITTING DISPLAY DEVICE

(71) Applicant: LG Display Co., Ltd., Seoul (KR)

(72) Inventors: Min-Ki Kim, Paju-si (KR); Ki-Soub Yang, Paju-si (KR); Sung-Goo Jung, Paju-si (KR); Jae-Hyung Yu, Paju-si (KR); Hak-Min Lee, Paju-si (KR); Jae-Hwan Myung, Paju-si (KR)

(21) Appl. No.: 19/651,787

(22) Filed: Apr. 20, 2026

(30) Foreign Application Priority Data
Apr. 29, 2025 (KR) 10-2025-0056106

(51) Int. Cl. H10K 59/35; H10K 59/38; H10K 59/80

(52) U.S. Cl. CPC H10K 59/351; H10K 59/38; H10K 59/878

(57) ABSTRACT

A light emitting display device includes: a substrate including a plurality of subpixels including red, green, blue, and white subpixels; a light emitting diode provided in each of the plurality of subpixels, and including a first electrode, a light emitting layer, and a second electrode stacked in a thickness direction, the second electrode including a transparent conductive material; a semi-transmissive plate disposed on the light emitting diodes of the red, green, blue, and white subpixels; and an insulating layer disposed on the semi-transmissive plate of the white subpixel.

### CROSS REFERENCE TO RELATED APPLICATION

This application claims priority from and the benefit of Korean Patent Application No. 10-2025-0056106, filed on Apr. 29, 2025, which is hereby incorporated by reference for all purposes as if fully set forth herein.

### BACKGROUND

### Field

Embodiments of the invention relate generally to a light emitting display device.

### Discussion of the Background

Recently, flat panel display devices with excellent characteristics such as thinness, weight reduction, and low power consumption have been widely developed and applied to various fields.

Among the flat panel display devices, light emitting display devices equipped with light emitting elements such as light emitting diodes are display devices that emit light when charges are injected into a light emitting layer formed between an anode and a cathode, and electrons and holes are paired and then extinguished.

In the light emitting display device, red, green, and blue subpixels may be configured with a micro-cavity structure to improve emission efficiency of corresponding colors. However, the light emitting display device employing the micro-cavity structure have difficulty in implementing a white subpixel.

The above information disclosed in this Background section is only for understanding of the background of the inventive concepts, and, therefore, it may contain information that does not constitute prior art.

### SUMMARY

Embodiments of the invention provide a light emitting display device with a micro-cavity structure that is capable of implementing a white subpixel.

Additional features of the inventive concepts will be set forth in the description which follows, and in part will be apparent from the description, or may be learned by practice of the inventive concepts.

According to an embodiment of the invention, a light emitting display device includes: a substrate including a plurality of subpixels including red, green, blue, and white subpixels; a light emitting diode provided in each of the plurality of subpixels, and including a first electrode, a light emitting layer, and a second electrode stacked in a thickness direction, the second electrode including a transparent conductive material; a semi-transmissive plate disposed on the light emitting diodes of the red, green, blue, and white subpixels; and an insulating layer disposed on the semi-transmissive plate of the white subpixel.

The second electrode may have a thickness in a range of about 10nm to about 65nm, the semi-transmissive plate has a thickness in a range of about 10nm to about 30nm, and the insulating layer has a thickness in a range of about 35nm to about 80nm.

The semi-transmissive plate may include Ag or AgMg.

The second electrode may include a transparent oxide conductive material.

The insulating layer may include a transparent oxide insulating material or transparent nitride insulating material.

The insulating layer may include Al₂O₃.

The light emitting diodes of the red, green, blue, and white subpixels may each configured to emit white light. First, second, third, and fourth reflective plates may be disposed below the light emitting diodes of the red, green, blue, and white subpixels, respectively. The first reflective plate may be disposed below the second reflective plate. The second reflective plate may be disposed below the third reflective plate.

The fourth reflective plate may be disposed on a same layer as one of the first, second, and third reflective plates.

The light emitting display device may include red, green, and blue color filter patterns disposed on the semi-transmissive plate in the red, green, and blue subpixels, respectively. The insulating layer may overlap the red, green, and blue color filter patterns.

According to another embodiment of the invention, a light emitting display device includes: a substrate including a plurality of subpixels including red, green, blue, and white subpixels; a light emitting diode provided in each of the plurality of subpixels, and including a first electrode, a light emitting layer, and a second electrode which are stacked in a thickness direction, the second electrode being transparent; a semi-transmissive plate disposed on the second electrode; and a dielectric layer disposed on the semi-transmissive plate of the white subpixel.

The second electrode may have a thickness in a range of about 10nm to about 65nm, the semi-transmissive plate has a thickness in a range of about 10nm to about 30nm, and the dielectric layer has a thickness in a range of about 35nm to about 80nm.

The semi-transmissive plate may include Ag or AgMg. The second electrode may include a transparent oxide conductive material. The dielectric layer may include a transparent oxide insulating material or transparent nitride insulating material.

According to still another embodiment of the invention, a light emitting display device includes: a substrate including a plurality of subpixels which include red, green, blue, and white subpixels; a light emitting diode provided in each of the plurality of subpixels, and including a first electrode, a light emitting layer, and a second electrode stacked in a thickness direction, the second electrode including a transparent conductive material; a semi-transmissive plate disposed on the light emitting diodes of the red, green, blue, and white subpixels; an insulating layer disposed on the semi-transmissive plate; and a first reflective electrode disposed in the red subpixel, a second reflective electrode disposed in the green subpixel, a third reflective electrode disposed in the blue subpixel, and a fourth reflective electrode disposed in the white subpixel.

The first reflective electrode may be disposed on a same layer as the fourth reflective electrode.

The second electrode may be disposed on a same layer as the fourth reflective electrode.

The third reflective electrode may be disposed on a same layer as the fourth reflective electrode.

A distance from the third reflective electrode to the semi-transmissive plate may be greater than a distance from the second reflective electrode to the semi-transmissive plate, a distance from the second reflective electrode to the semi-transmissive plate may be greater than a distance from the first reflective electrode to the semi-transmissive plate, and a distance from the third reflective electrode to the semi-transmissive plate may be greater than a distance from the first reflective electrode to the semi-transmissive plate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a plan view schematically illustrating a light emitting display device according to an embodiment of the invention.

FIG. 2 is a schematic cross-sectional view taken along line II-II’ of FIG. 1.

FIGS. 3, 4A, 4B, 5A, 5B, 6A, 6B, 6C and 6D are schematic views showing simulation results for visible light transmittance when a stacked structure of second electrode/semi-transmissive plate/insulating layer according to an embodiment of the invention is applied.

FIG. 7 is a cross-sectional view schematically illustrating a light emitting display device according to another embodiment of the invention.

FIG. 8 is a cross-sectional view schematically illustrating a light emitting display device according to a still another embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

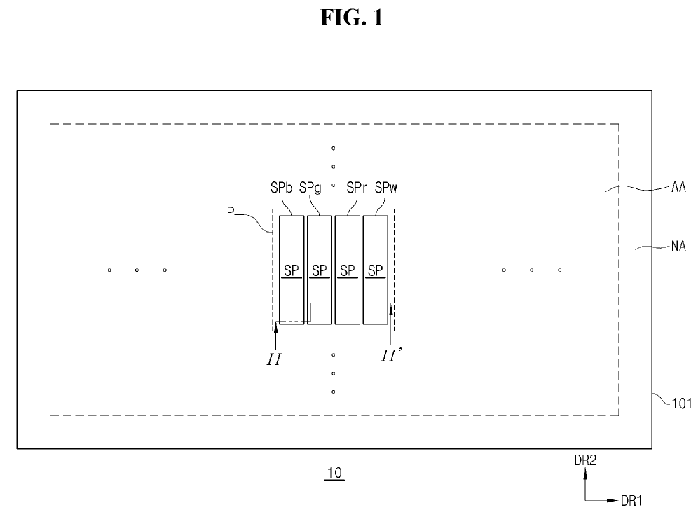

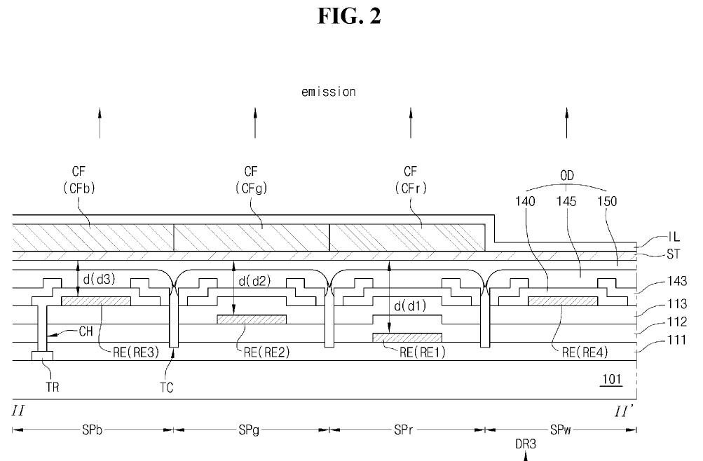

FIG. 1 is a plan view schematically illustrating a light emitting display device according to an embodiment of the invention. FIG. 2 is a cross-sectional view taken along line II-II’ of FIG. 1, schematically illustrating a cross-sectional structure of subpixels.

Prior to a detailed description, the light emitting display device 10 according to an embodiment of the invention may include any type of display device that displays images using a light emitting diode OD which is a self-luminous element.

In this embodiment, for convenience of explanation, an organic light emitting display device may be used as the light emitting display device 10.

The light emitting display device 10 may be a top emission type or bottom emission type display device. In this embodiment, for convenience of explanation, a top emission type light emitting display device 10 may be used as an example.

Referring to FIGS. 1 and 2, the light emitting display device 10 (or its light emitting display panel) of this embodiment may include a display region AA for displaying an image and a non-display region NA arranged around the display region AA.

The display region AA may include a plurality of subpixels SP arranged along a plurality of row lines (or horizontal lines) and a plurality of column lines (or vertical lines) disposed on a substrate 101.

Meanwhile, although not specifically illustrated, a plurality of gate lines (or scan lines) extending along the row direction (or horizontal direction or first direction) DR1 and a plurality of data lines extending along the column direction (or vertical direction or second direction) DR2 may be formed on the substrate 101. Each subpixel SP may be connected to corresponding gate line and data line.

Furthermore, a power line transmitting a high-potential driving voltage and a power line transmitting a low-potential driving voltage may be formed on the substrate 101. The high-potential driving voltage and the low-potential driving voltage may be applied to the subpixel SP.

The plurality of subpixels SP formed on the substrate 101 may include subpixels SP of different colors that constitute a pixel P which is a unit for displaying a color image. For example, the subpixels SP constituting the pixel P may include subpixels SP that display (or emit) first, second, and third colors, respectively. For example, red, green, and blue subpixels SPr, SPg, and SPb may display (or emit) red, green, and blue, respectively. In addition, the subpixels SP constituting the pixel P may further include a white subpixel SPw that displays (or emits) white.

As such, in this embodiment, each pixel P may have an RGBW structure configured with the red, green, blue, and white subpixels SPr, SPg, SPb, and SPw.

As the white subpixel SPw may be provided in the pixel P, a white balance in the light emitting display device 10 may be improved and a luminance may be increased.

The red, green, blue, and white subpixels SPr, SPg, SPb, and SPw may be arranged in various configurations. For example, as illustrated in FIG. 1, the subpixels SP may be arranged in a stripe type, in which subpixels SP of the same color are arranged in the column direction DR2 and subpixels SP of different colors are alternately arranged in the row direction DR1, without being imited thereto.

Each subpixel SP may include a light emitting diode OD which is a light emitting element. Furthermore, the subpixel SP may include a pixel driving circuit that drives the light emitting diode OD. The pixel driving circuit may include a plurality of thin film transistors TR including a driving transistor, and at least one capacitor. In this case, during an emission period, the driving transistor may be turned on to generate an emission current, and the emission current may be provided to the light emitting diode OD to perform an emission operation.

The light emitting diodes ODs having the same emission characteristics may be formed in the red, green, blue, and white sub-pixels SPr, SPg, SPb, and SPw that constitute the pixel P. More specifically, white light emitting diodes OD that substantially emit white light may be formed identically in the subpixels SP that constitute the pixel P.

Each of the red, green, and blue subpixels SPr, SPg, and SPb provided in the pixel P may be implemented with a micro-cavity structure in order to increase emission efficiency of its corresponding color, and the micro-cavity structure may be configured with a semi-transmissive laminated film and a reflective laminated film that are arranged vertically with a light emitting layer 145 interposed therebetween.

In this regard, for example, the red subpixel SPr, the green subpixel SPg, and the blue subpixel SPb may emit light of different colors, i.e., different wavelengths, and thus they may have different cavity thicknesses, i.e., resonant distances (d: d1, d2, and d3).

In this regard, the red, green, and blue subpixels SPr, SPg, and SPb may have the resonant distances d proportional to their color wavelengths (or half-wavelengths). The resonant distance d of each subpixel SP may be matched to an integer multiple of the half-wavelength of its corresponding color. In this case, the resonant distance d may be defined in a third direction DR3 (in a thickness direction).

In this regard, the red subpixel SPr, which outputs a color of the longest wavelength, may have a first resonant distance d1. The green subpixel SPg, which outputs a color of the middle wavelength, may have a second resonant distance d2 smaller than the first resonant distance d1. The blue subpixel SPb, which outputs a color of the shortest wavelength, may have a third resonant distance d3 smaller than the second resonant distance d2. In other words, the first distance d1 may be greater than the second distance d2, the second distance d2 may be greater than the third distance d3, and the first distance d1 may be greater than the third distance d3.

As such, by applying the micro-cavity structures to the red, green, and blue subpixels SPr, SPg, and SPb, purity and emission efficiency of their corresponding colors may be improved.

In this embodiment, in implementing the resonant distances d of the red, green, and blue subpixels SPr, SPg, and SPb, a semi-transmissive plate (or semi-transmissive electrode) ST, which is a laminated film having semi-transmissive characteristics and positioned on an upper side in an upper direction that is a light output direction of the micro-cavity structure, may be substantially placed on the light emitting diodes OD.

In addition, in implementing the resonant distances d of the red, green, and blue subpixels SPr, SPg, and SPb, reflective plates (or reflective electrodes) RE, which are laminated films having reflective characteristics and positioned on a lower side in a lower direction that is opposite to a light output direction of the micro-cavity structure, may be substantially placed below the light emitting diodes OD.

In this embodiment, a position (or height) at which the reflective plate RE is placed may be differentiated among the red, green, and blue subpixels SPr, SPg, and SPb. In other words, the reflective plates (RE: RE1, RE2, and RE3) of the red, green, and blue subpixels SPr, SPg, and SPb may be formed individually and positioned on different planes.

Furthermore, a position (or a height) at which the semi-transmissive plate ST is placed may be configured to be substantially the same among the red, green, and blue subpixels SPr, SPg, and SPb. For example, the semi-transmissive plate ST of the red, green, and blue subpixels SPr, SPg, and SPb may be formed integrally and positioned on substantially the same plane.

As such, in this embodiment, by varying the positions of the reflective plates RE of the red, green, and blue subpixels SPr, SPg, and SPb, the resonance distances d of their corresponding micro-cavity structures may be implemented.

In addition, in the red, green, and blue subpixels SPr, SPg, and SPb, their corresponding color filter patterns (CF: CFr, CFg, and CFb) may be laminated on the semi-transmissive plate ST.

Meanwhile, similar to the red, green, and blue subpixels SPr, SPg, and SPb, the white subpixel SPw may include the reflective plate (RE: RE4) and the semi-transmissive plate ST which are formed below and on the corresponding light emitting diode OD, respectively.

The semi-transmissive plate ST of the white subpixel SPw may be positioned, for example, substantially on the same plane as the semi-transmissive plate ST of the red, green, and blue subpixels SPr, SPg, and SPb.

For example, the semi-transmissive plate ST of the red, green, blue, and white subpixels SPr, SPg, SPb, and SPw may be formed integrally and positioned substantially on the same plane. In other words, a single semi-transmissive plate ST may be formed substantially over the entire display region AA, so that the single semi-transmissive plate ST may be integrally formed across all subpixels SPs.

The reflective plate (RE: RE4) of the white subpixel SPw may be formed, for example, at the same position (or on a same layer) as the reflective plate RE of one of the red, green, and blue subpixels SPr, SPg, and SPb. In this embodiment, a case in which the reflective plate RE of the white subpixel SPw is formed on the same plane as the reflective plate RE of the blue subpixel SPb may be taken as an example.

The white subpixel SPw may be configured such that a separate color filter pattern CF is not formed.

Meanwhile, on the color filter patterns CF of the red, green, and blue subpixels SPr, SPg, and SPb and the semi-transmissive plate ST of the white subpixel SPw, an insulating layer (or dielectric layer) IL which is formed of a dielectric may be formed. The insulating layer IL may, for example, be formed substantially over the entire substrate 101 and function as an encapsulation layer. Furthermore, the insulating layer IL may have a transparent property that substantially transmits visible light.

The insulating layer IL may be formed on an upper surface of the semi-transmissive plate ST in the white subpixel SPw. Furthermore, a second electrode (or cathode) 150, which serves as an upper electrode of the light emitting diode OD and is a transparent electrode having transparent characteristics, may be formed below a lower surface of the semi-transmissive plate ST.

As such, the white subpixel SPw may have a structure in which the second electrode 150, the semi-transmissive plate ST, and the insulating layer IL are sequentially stacked.

The transparent second electrode 150 may be formed of a transparent oxide conductive material, such as ITO, IZO, or ZnO.

The insulating layer IL may be formed of a transparent oxide insulating material, such as Al₂O₃ or SiO₂, or a transparent nitride insulating material, such as SiNₓ. In this embodiment, a case in which the insulating layer IL is formed of an oxide insulating material may be taken as an example.

According to the stacked structure of the second electrode 150/semi-transmissive plate ST/insulating layer IL, a transmittance of the semi-transmissive plate ST may substantially increase across the entire visible light wavelength range.

Accordingly, the micro-cavity effect is not effectively exerted in the white subpixel SPw, but rather, a non-micro-cavity effect, in which visible light is transmitted throughout the entire visible light spectrum, may be exerted.

In other words, although the semi-transmissive plate ST exists in the white subpixel SPw, due to the stacked structure of the second electrode 150/semi-transmissive plate ST/insulating layer IL, the semi-transmissive plate ST may actually perform a transmission function instead of a semi-transmission function.

As such, in this embodiment, the semi-transmissive plate ST may be formed not only in the red, green, and blue subpixels SPr, SPg, and SPb but also in the white subpixel SPw, and the insulating layer IL may be stacked on the semi-transmissive plate ST of the white subpixel SPw, so that the red, green, and blue subpixels SPr, SPg, and SPb may be configured with the micro-cavity structure that implements their corresponding color light, and the white subpixel SPw may be configured with a non-micro-cavity structure that substantially transmits and outputs white light.

Accordingly, the semi-transmissive plate ST may be formed across the entire subpixels SP without need for a separate process to remove the semi-transmissive plate ST from the white subpixel SPw. Thus, manufacturing processes may be simplified while effectively implementing the white subpixel SPw.

Configuration and implementation method of the RGBW structure of this embodiment may be described in more detail below.

Referring to FIG. 2, the cross-sectional structures of the red, green, and blue subpixels SPr, SPg, and SPb having the micro-cavity structure and the white subpixel SPw having the non-micro-cavity structure may be described.

The substrate 101 of the light emitting display device 10 may be, for example, an insulating substrate, such as a glass substrate or a plastic substrate. Alternatively, the substrate 101 may be a silicon substrate (or silicon wafer) formed of crystalline silicon (e.g., single crystal silicon) that functions as a semiconductor, and in this case, there is an advantage of effectively implementing a small-sized display device requiring high resolution.

In this embodiment, for convenience of explanation, an insulating substrate is used as an example.

A plurality of thin film transistors TR may be formed in each subpixel SP on the substrate 101. Meanwhile, in this embodiment, for convenience of explanation, in FIG. 2, one thin film transistor TR connected to the light emitting diode OD is illustrated in the left blue subpixel SPb. The thin film transistor TR may be an emission control transistor or a driving transistor, without being limited thereto.

Although not specifically illustrated, the thin film transistor TR may include a semiconductor layer, a gate insulating film, a gate electrode, a source electrode, and a drain electrode. Here, the thin film transistor TR may be a thin film transistor of a bottom-gate structure in which the gate electrode is positioned below the semiconductor layer, or a thin film transistor of a top-gate structure in which the gate electrode is positioned over the semiconductor layer.

The semiconductor layer of the thin film transistor TR may be formed of, for example, oxide semiconductor, crystalline silicon, amorphous silicon, or the like, but is not limited thereto.

Meanwhile, in a case where a semiconductor substrate is used as the substrate 101, an active region functioning as a semiconductor layer may be formed within the semiconductor substrate.

At least one passivation layer (or insulating layer) may be formed on the thin film transistor TR. In this embodiment, for convenience of explanation, a case where three passivation layers, first passivation layer 111 to third passivation layer 113, are formed may be taken as an example.

The first passivation layer 111 may be formed substantially over the entire surface of the substrate 101, covering (or overlapping) the thin film transistor TR. The first passivation layer 111 may be formed of an organic insulating material and/or an inorganic insulating material.

The first reflective plate (or first reflective electrode) (RE: RE1) may be formed on the first passivation layer 111 in the red subpixel SPr.

The second passivation layer 112 may be formed on the first passivation layer 111 on which the first reflective plate RE1 is formed, substantially over the entire surface of the substrate 101. The second passivation layer 112 may be formed of an organic insulating material and/or an inorganic insulating material.

The second reflective plate (or second reflective electrode) (RE:RE2) may be formed on the second passivation layer 112 in the green subpixel SPg.

The third passivation layer 113 may be formed on the second passivation layer 112 on which the second reflective plate RE2 is formed, substantially over the entire surface of the substrate 101. The third passivation layer 113 may be formed of an organic insulating material and/or an inorganic insulating material.

The third reflective plate (or third reflective electrode) (RE:RE3) may be formed on the third passivation layer 113 in the blue subpixel SPb.

Furthermore, the fourth reflective plate (or fourth reflector electrode) (RE:RE4) may be formed on the third passivation layer 113 in the white subpixel SPw.

The first, second, third, and fourth reflective plates RE1, RE2, RE3, and RE4 may be formed of a highly reflective metal, such as, but not limited to, Ag, Al, Mo, Ti, or an APC (Al-Pd-Cu) alloy.

Meanwhile, a contact hole CH exposing one electrode of the thin film transistor TR, for example, a drain electrode, may be formed in the first, second, and third insulating layers 111, 112, and 113.

The first, second, third, and fourth reflective plates RE1, RE2, RE3, and RE4 may each function to reflect upward light which is generated from the light emitting diode OD in the corresponding subpixels SP and propagates downward.

On the substrate 101 on which the first, second, third and fourth reflective plates RE1, RE2, RE3 and RE4 are formed, a first electrode (or anode) 140 of the light emitting diode OD may be formed for each subpixel SP. The first electrode 140 may be formed in a patterned form for each subpixel SP.

The first electrode 140 may be formed of a transparent conductive material, such as ITO, IZO, or ZnO.

The first electrode 140 in each of the red subpixel SPr and the green subpixel SPg may be formed on the third passivation layer 113. In addition, the first electrode 140 in the blue subpixel SPb may be formed on the third reflective plate RE3, and the first electrode 140 in the white subpixel SPw may be formed on the fourth reflective plate RE4.

The first electrode 140 formed in each subpixel SP may be connected to the drain electrode of the thin film transistor TR of each subpixel SP through the contact hole CH.

A bank (or partition wall or fence) 143 positioned along an edge of each subpixel SP surrounding the subpixel SP may be formed on the first electrode 140. The bank 143 may be made of an inorganic or organic insulating material.

The bank 143 may have an opening that exposes the first electrode 140 of each subpixel SP and may be configured to cover (or overlap) an edge of the first electrode 140. By the opening of the bank 143, an emission region (or light emitting diode OD) where light is actually generated within the subpixel SP may be defined.

A trench TC may be formed in the bank 143 and at least a portion of the passivation layers 111, 112, and 113 below the bank 143. For example, the trench TC may be formed along a boundary between the subpixels SP of different colors in the column direction (or in the second direction) DR2. In some cases, a trench TC may also be formed along a boundary between the subpixels SP of the same color in the row direction (or in the first direction) DR1.

As such, by forming the trench TC, lateral leakage current between adjacent subpixels SP may be prevented.

In this embodiment, for convenience of explanation, a case where the trench TC is formed in the third passivation layer 113 to the first passivation layer 111 may be taken as an example. Alternatively, the trench TC may be formed in the third passivation layer 113 or in the third and second passivation layers 113 and 112. As such, among the first passivation layer 111 to the third passivation layer 113, the trench TC may be formed in at least one passivation layer, including the third passivation layer 113.

A light emitting layer 145 may be formed on the bank 143 and on the first electrode 140 exposed through the opening of the bank 143. The light emitting layer 145 may be formed substantially over the entire substrate 101 (or the entire display region AA).

The light emitting layer 145 may be, for example, an organic light emitting layer formed using an organic material. The light emitting layer 145 may be formed with a multi-layered structure including an emitting material layer that actually emits light.

The light emitting layer 145 (or at least a portion of the light emitting layer 145) may be separated (or disconnected or divided) by the trench TC formed in the bank 143 and the first, second, and third passivation layers 111, 112, and 113.

The light emitting layer 145 may be formed with a single-stack structure or a multi-stack structure.

When the light emitting layer 145 is formed with a single-stack structure, the light emitting layer 145 may be separated by the trench TC.

Meanwhile, when the light emitting layer 145 is configured with a multi-stack structure, a charge generation layer may be provided between vertically adjacent stacks. In this case, for example, a lower stack and the charge generation layer on the lower stack may be separated by a trench TC, and an upper stack may be configured such that at least an upper portion of the upper stack is not separated over the trench TC and is connected over the trench TC.

The light emitting layer 145 may be configured as, for example, a white light emitting layer that emits white light. Accordingly, the light emitting diodes OD of all subpixels SP may emit the same white light.

A second electrode (or cathode) 150 may be formed on the light emitting layer 145 and substantially over the entire surface of the substrate 101.

In this regard, the second electrode 150 may be formed continuously between adjacent subpixel SP without being separated by the trench TC. Accordingly, the second electrode 150 may be formed continuously along all subpixels SP of the display region AA.

As such, the second electrode 150 may be formed by deposition along all subpixels SP without a separate patterning process.

The second electrode 150 may be formed of a transparent electrode having a transmissive characteristics. The second electrode 150 may be formed of a transparent oxide conductive material, such as ITO, IZO, or ZnO, but is not limited thereto.

The first electrode 140, the light emitting layer 145, and the second electrode 150, stacked as described above, may form the light emitting diode OD. Accordingly, the light emitting diode OD may be formed in each subpixel SP.

As mentioned above, the light emitting diode OD may be configured to the light emitting layer 145 that emits white light, and thus may serve as a white light emitting diode.

As such, the subpixels SP within the display region AA may have the light emitting diodes OD of substantially the same structure, so that uniformity in emission characteristics may be ensured among the subpixels SP.

The semi-transmissive plate ST may be formed substantially over the entire surface of the substrate 101 having the light emitting diode.

In this regard, similar to the second electrode 150, the semi-transmissive plate ST may be formed continuously between adjacent subpixels SP without being separated, within the display region AA. Accordingly, the semi-transmissive plate ST may be formed substantially continuously along all subpixels SP of the display region AA.

As such, the semi-transmissive plate ST may be formed by deposition along all subpixels SP i.e., red, green, blue, and white subpixels SPr, SPg, SPb, and SPw, without a separate patterning process.

The semi-transmissive plate ST may be formed of, for example, a metal that exhibits semi-transmissive characteristics, such as, but not limited to, Ag or an alloy of Ag and Mg (AgMg).

The semi-transmissive plate ST positioned in the red, green, and blue subpixels SPr, SPg, and SPb may implement the micro-cavity structure together with the reflective plates (RE: RE1, RE2, and RE3) positioned below the light-emitting diodes OD of the subpixels SPr, SPg, and SPb.

In this regard, in the red subpixel SPr, the first reflective plate RE1 and the semi-transmissive plate ST may be spaced apart from each other by the first resonant distance d1 for red light emission. Accordingly, in the red subpixel SPr, the micro-cavity structure configured with the first reflective plate RE1 and the semi-transmissive plate ST may be implemented. Accordingly, in the red subpixel SPr, white light generated from the light emitting diode OD may be reflected between the first reflective plate RE1 and the semi-transmissive plate ST of the micro-cavity structure, thereby producing (or outputting) red light upward.

In the green subpixel SPg, the second reflective plate RE2 and the semi-transmissive plate ST may be spaced apart from each other by the second resonant distance d2 for green light emission. Accordingly, in the green subpixel SPg, the micro-cavity structure configured with the second reflective plate RE2 and the semi-transmissive plate ST may be implemented. Accordingly, in the green subpixel SPg, white light generated from the light emitting diode OD may be reflected between the second reflective plate RE2 and the semi-transmissive plate ST of the micro-cavity structure, thereby producing (or outputting) green light upward.

In the blue subpixel SPb, the third reflective plate RE3 and the semi-transmissive plate ST may be spaced apart from each other by the third resonant distance d3 for blue light emission. Accordingly, in the blue subpixel SPb, the micro-cavity structure configured with the third reflective plate RE3 and the semi-transmissive plate ST may be implemented. Accordingly, in the blue subpixel SPb, white light generated from the light emitting diode OD may be reflected between the third reflective plate RE3 and the semi-transmissive plate ST of the micro-cavity structure, thereby producing (or outputting) blue light upward.

A color filter pattern CF may be formed on the semi-transmissive plate ST corresponding to each of the red, green, and blue subpixels SPr, SPg, and SPb.

For example, for the red subpixel SPr, a red color filter pattern (or first color filter pattern) CFr may be formed on the semi-transmissive plate ST. As such, by arranging the red color filter pattern CFr directly disposed on the semi-transmissive plate ST, color purity may be improved.

For the green subpixel SPg, a green color filter pattern (or second color filter pattern) CFg may be formed on the semi-transmissive plate ST. As such, by directly arranging the green color filter pattern CFg directly disposed on the semi-transmissive plate ST, color purity may be improved.

For the blue subpixel SPb, a blue color filter pattern (or third color filter pattern) CFb may be formed on the semi-transmissive plate ST. As such, by arranging the blue color filter pattern CFb directly disposed on the semi-transmissive plate ST, color purity may be improved.

Meanwhile, a separate color filter pattern CF may not be formed on the white subpixel SPw.

On the substrate 101 on which the color filter patterns (CF: CFr, CFg, and CFb) are formed, the insulating layer IL may be formed substantially over the entire surface of the substrate 101. The insulating layer IL may be formed of, for example, a transparent oxide insulating material such as Al₂O₃ or SiO₂, or a transparent nitride insulating material such as SiNₓ, without being limited thereto. Meanwhile, in the illustrated embodiment, the insulating layer IL is exemplarily described as being formed of an oxide insulating material.

As such, the insulating layer IL may be formed to substantially cover (or overlap) the entire subpixels SP arranged on the substrate 101, and may function as an encapsulating layer that seals the light emitting diodes OD.

More specifically, the insulating layer IL arranged on the red, green, and blue subpixels SPr, SPg, and SPb may be formed to cover the red, green, and blue color filter patterns CFr, CFg, and CFb.

Meanwhile, the insulating layer IL arranged on the white subpixel SPw may be formed to contact an upper surface of the semi-transmissive plate ST of the white subpixel SPw. In other words, the insulating layer IL may be formed directly on the semi-transmissive plate ST of the white subpixel SPw that is not covered by the color filter pattern CF and is exposed.

As such, in the white subpixel (SPw), a structure in which the second electrode 150, the semi-transmissive plate ST, and the insulating layer IL are sequentially stacked may be implemented.

As previously mentioned, the transparent second electrode 150 may be formed of a transparent oxide conductive material, and the insulating layer IL may be formed of a transparent oxide insulating material (or transparent nitride insulating material).

According to this stacked structure of the second electrode 150/semi-transmissive plate ST/insulating layer IL, the transmittance of the semi-transmissive plate ST in the white subpixel SPw may substantially increase across the entire wavelength range of visible light.

Accordingly, the micro-cavity effect may not be substantially realized in the white subpixel SPw, but rather, a non-micro-cavity effect, in which visible light is transmitted throughout the entire spectrum of visible light, may be realized.

In other words, although the semi-transmissive plate ST exists in the white subpixel SPw, due to the stacked structure of the second electrode 150/semi-transmissive plate ST/insulating layer IL, the semi-transmissive plate ST in the white subpixel SPw may actually perform a transmission function instead of a semi-transmissive function.

In this regard, the semi-transmissive plate ST may have a semi-transmissive characteristics by forming a metal with a certain thickness (e.g., in a range of about 10 nm to about 30 nm), and the semi-transmissive plate ST may reflect light as free electrons present on the metal surface react with the light energy.

Generally, the semi-transmissive plate ST may have characteristics in which due to a unique frequency of the metal's free electrons, a transmittance peak exists in an ultraviolet region, and transmittance decreases as the wavelength increases in the visible region.

However, when an oxide (or nitride) is placed on the surface of the semi-transmissive plate ST, the free electrons of the metal react with the oxide, causing a transmittance distribution for a wavelength to shift to a visible light region, resulting in an overall increase in the transmittance in the visible light region.

Accordingly, in the white subpixel SPw, by arranging the second electrode 150 and the insulating layer IL formed of oxide which are on the lower and upper surfaces of the semi-transmissive plate ST, the stacked structure of the second electrode 150/semi-transmissive plate ST/insulating layer IL may be formed, so that the white subpixel SPw may stably (or effectively) obtain transmission characteristics of white light.

As such, in this embodiment, it is possible that the white subpixel SPw is configured with the non-micro-cavity structure that substantially transmits and outputs white light generated from the light emitting diode OD.

Accordingly, there may be no need to perform a separate patterning process to remove the semi-transmissive plate ST for the white subpixel SPw, and instead, the semi-transmissive plate ST may be formed in the white subpixel SP. Thus, the manufacturing process may be simplified while effectively implementing the white subpixel SPw.

In this regard, in order to form the micro-cavity structure in the red, green, and blue sub-pixels SPr, SPg, and SPb and the non-micro-cavity structure in the white sub-pixel SPw, a method of depositing a second electrode 150 with a semi-transmissive characteristics over the entire surface of the substrate 101 and removing this second electrode 150 corresponding to the white sub-pixel SPw through an etching process may be considered. However, in this case, since the light emitting layer 145 is located below the second electrode 150 with the semi-transmissive characteristics, there may be a risk that the light emitting layer 145 is damaged during the etching process, and therefore this method is not practically applicable.

On the other hand, in this embodiment, the second electrode 150 may be formed as a transparent electrode, the semi-transmissive plate ST on the second electrode 150 may be formed over the entire substrate 101, and the insulating layer IL may be formed on the upper surface of the semi-transmissive plate ST in the white sub-pixel SPw. Accordingly, while the red, green, and blue subpixels SPr, SPg, and SPb may be implemented with the micro-cavity structures corresponding to the colors of the red, green, and blue subpixels SPr, SPg, and SPb, the white subpixel SPw may be implemented with the non-micro-cavity structure capable of emitting white light.

As such, according to this embodiment, the semi-transmissive plate ST may be formed across the entire subpixels SP without need for a separate process of removing the semi-transmissive plate ST in the white subpixel SPw, thereby simplifying the manufacturing process and effectively implementing the white subpixel SPw.

Meanwhile, in order to secure visible light transmittance (i.e., white light transmittance) above an appropriate level according to the stacked structure of the second electrode 150/semi-transmissive plate ST/insulating layer IL in the white subpixel SPw, a thickness of each of the second electrode 150, the semi-transmissive plate ST, and the insulating layer IL may be set to a specific range.

In this regard, for example, to achieve the semi-transmissive characteristics and implement the micro-cavity structure in the red, green, and blue subpixels SPr, SPg, and SPb, the semi-transmissive plate ST may be formed at a thickness in a range of about 10 nm to about 30 nm.

Furthermore, to achieve the transmissive characteristics in the white subpixel SPw through the stacked structure of the second electrode 150, the semi-transmissive plate ST, and the insulating layer IL, the second electrode 150 below the semi-transmissive plate ST may be formed with a thickness in a range of about 10 nm about 65 nm, and the insulating layer IL on the semi-transmissive plate ST may be formed with a thickness in a range of about 35 nm to about 80 nm.

As such, when the second electrode 150, the semi-transmissive plate ST, and the insulating layer IL are sequentially stacked with the above-described thickness range, micro-cavity structures configured to implement red, green, and blue colors may be provided in the red, green, and blue sub-pixels SPr, SPg, and SPb. Meanwhile, the white sub-pixel SPw may exhibit a high level of transmittance of visible light passing through the semi-transmissive plate ST, thereby enabling a non-micro-cavity structure to be effectively implemented in the white sub-pixel SPw.

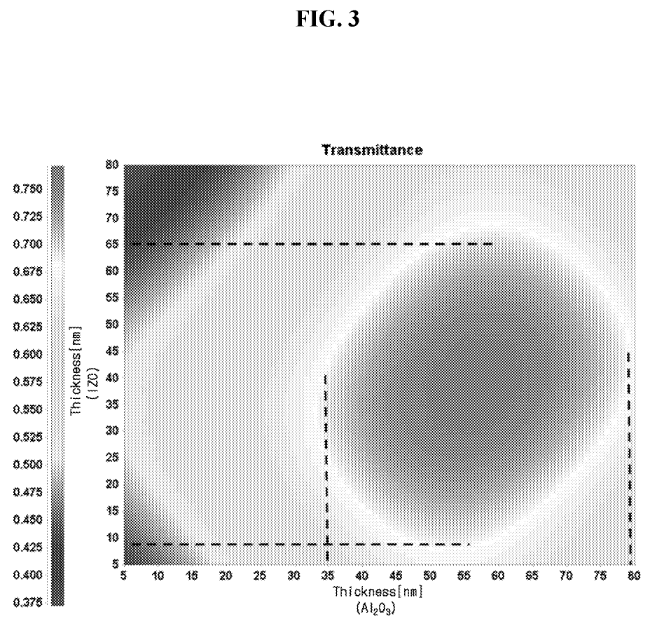

FIGS. 3, 4, 5, and 6 are views showing simulation results for visible light transmittance when a stacked structure of the second electrode/semi-transmissive plate/insulating layer according to an embodiment of the invention is applied. The simulation results are shown when the second electrode is formed of IZO, the semi-transmissive plate is formed of AgMg, and the insulating layer is formed of Al₂O₃.

More specifically, FIG. 3 is a view illustrating a visible light transmittance according to thicknesses of the second electrode and the insulating layer when a thickness of the semi-transmissive plate is about 18 nm.

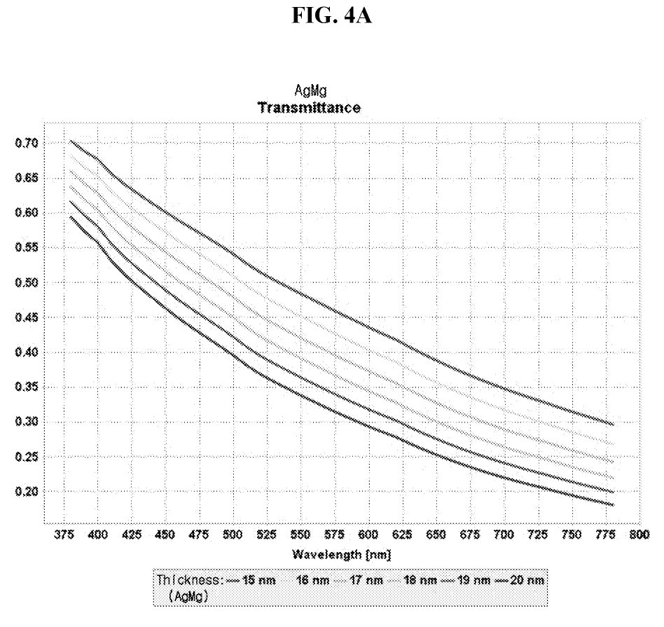

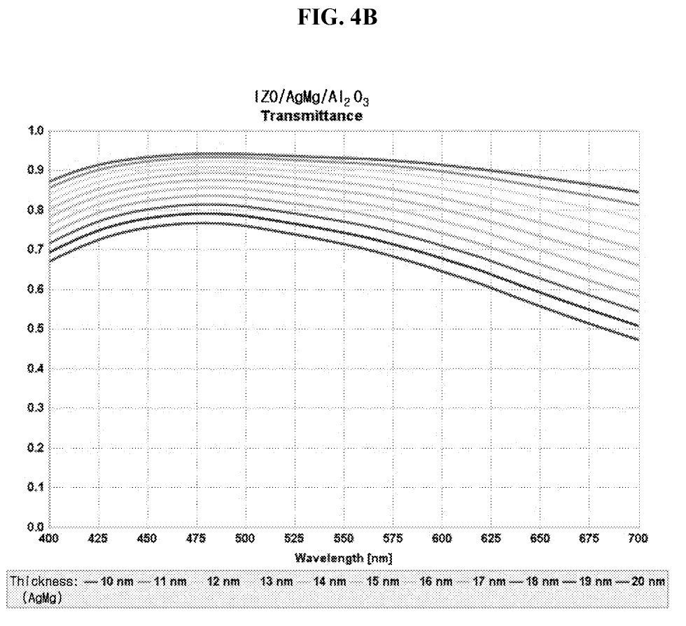

FIG. 4A is a view illustrating a visible light transmittance of the semi-transmissive plate according to a thickness (about 15 nm to about 20 nm) of the semi-transmissive plate, and FIG. 4B is a view illustrating a visible light transmittance of a stacked structure of the second electrode/semi-transmissive plate/insulating layer according to a thickness (about 10 nm to about 20 nm) of the semi-transmissive plate. In FIG. 4B, a thickness of the second electrode is about 40 nm and a thickness of the insulating layer is about 40 nm.

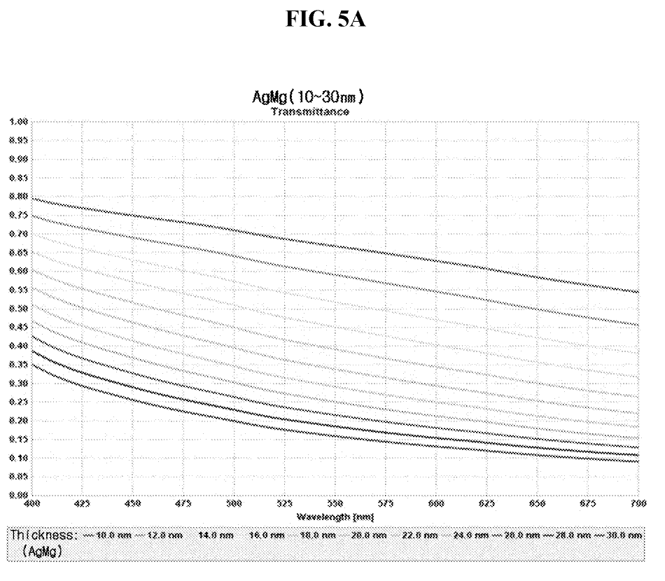

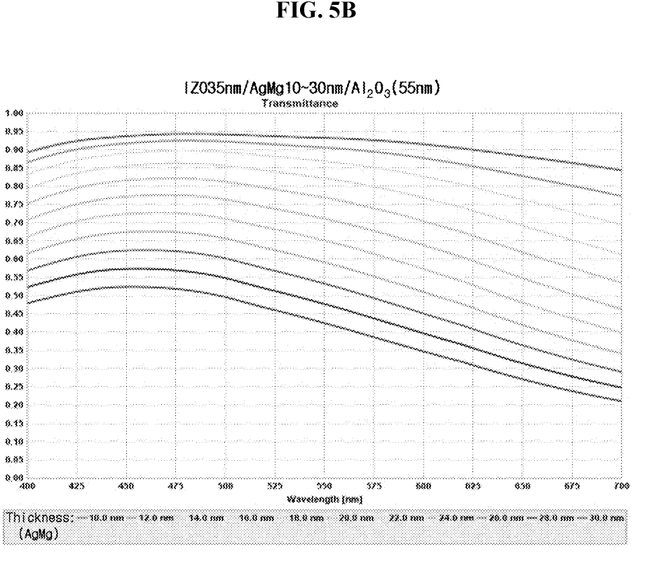

FIG. 5A is a view a visible light transmittance of the semi-transmissive plate according to a thickness (about 10 nm to about 30 nm) of the semi-transmissive plate, and FIG. 5B is a view illustrating a visible light transmittance of a stacked structure of the second electrode/semi-transmissive plate/insulating layer according to a thickness (about 10 nm to about 30 nm) of the semi-transmissive plate. In FIG. 5B, a thickness of the second electrode is about 35 nm and a thickness of the insulating layer is about 55 nm.

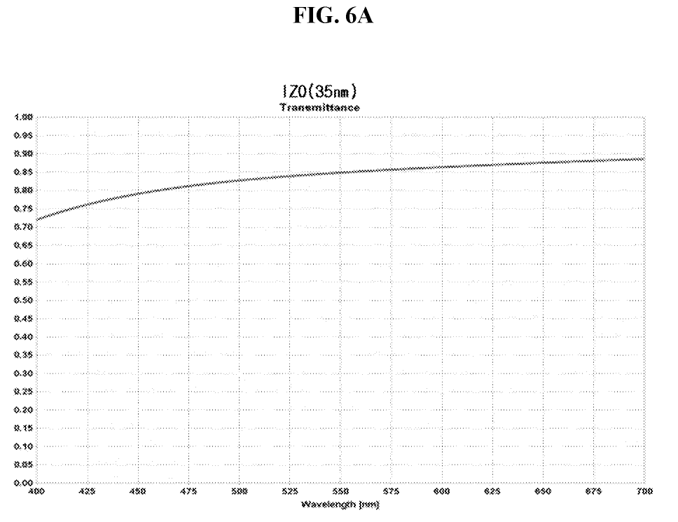

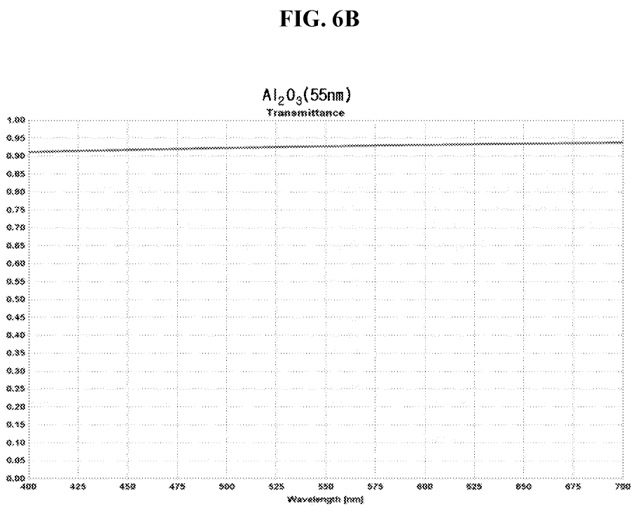

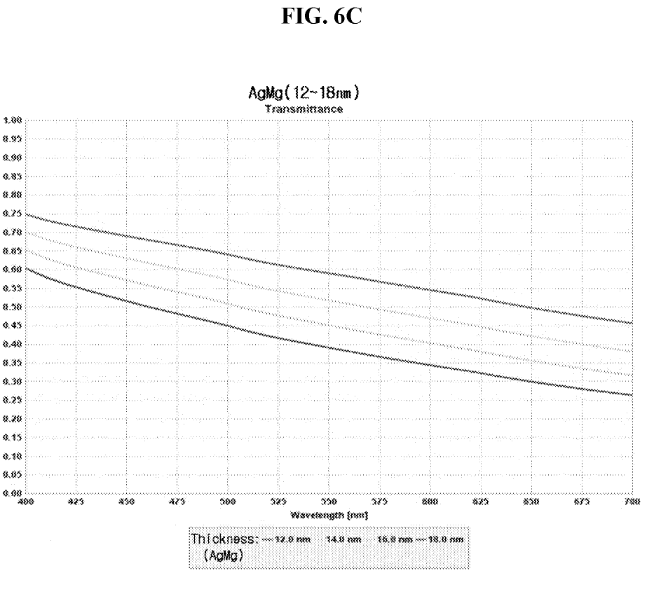

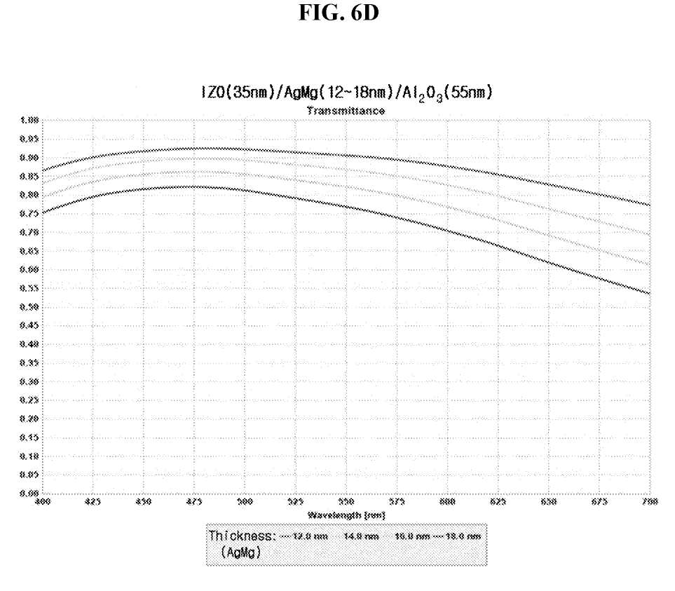

FIG. 6A is a view illustrating a visible light transmittance of the second electrode when a thickness of the second electrode is about 35 nm, FIG. 6B is a view illustrating a visible light transmittance of the insulating layer when a thickness of the insulating layer is about 55 nm, FIG. 6C is a view illustrating a visible light transmittance of the semi-transmissive plate when a thickness of the semi-transmissive plate is in a range of about 12 nm to about 18 nm, and FIG. 6D is a view illustrating a visible light transmittance of the stacked structure of the second electrode (about 35 nm)/semi-transmissive plate (about 12 nm to about 18 nm)/insulating layer (about 55 nm).

Regarding transmittance graphs in each of FIGS. 4A, 4B, 5A, 5B, 6C, and 6D, as a thickness increases, a transmittance graph is arranged sequentially in a downward direction. For example, in FIG. 4A, a transmittance graph corresponding to a thickness of about 15 nm is located over a transmittance graph corresponding to a thickness of about 16 nm.

Referring to FIG. 3, in a case where the semi-transmissive plate ST is 18 nm, when the second electrode 150 is set to about 10 nm to about 65 nm and the insulating layer IL is set to about 35 nm to about 80 nm, the visible light transmittance of the stacked structure of the second electrode 150/semi-transmissive plate ST/insulating layer IL is about 0.750 or more, so that a very high level of the transmittance may be secured.

In addition, referring to FIG. 4, it may be seen that the visible light transmittance of the semi-transmissive plate ST itself decreases to a very low level as the wavelength increases. On the other hand, when applying the stacked structure of the second electrode 150/semi-transmissive plate ST/insulating layer IL, its visible light transmittance thereof increases to a very high level throughout the visible light range.

In addition, referring to FIG. 5, similar to FIG. 4, it may be seen that the visible light transmittance of the semi-transmissive plate ST itself decreases to a very low level as the wavelength increases. On the other hand, when applying the stacked structure of the second electrode 150/semi-transmissive plate ST/insulating layer IL, its visible light transmittance increases to a significantly high level throughout the visible light range.

In addition, referring to FIG. 6, it may be seen that the visible light transmittance of the second electrode 150 itself and the visible light transmittance of the insulating layer IL itself are generally high, while the visible light transmittance of the semi-transmissive plate ST itself decreases to a very low level as the wavelength increases. On the other hand, when applying the stacked structure of the second electrode 150/semi-transmissive plate ST/insulating layer IL, its visible light transmittance increases to a significantly high level throughout the visible light range.

As such, by applying the stacked structure of the second electrode 150/semi-transmissive plate ST/insulating layer IL to the white subpixel SPw, the visible light transmittance of the white subpixel SPw may substantially increase across the entire wavelength range of visible light.

Therefore, the micro-cavity effect is not substantially realized in the white subpixel SPw, and instead, the non-micro-cavity effect in which the generated visible light is entirely transmitted may be realized.

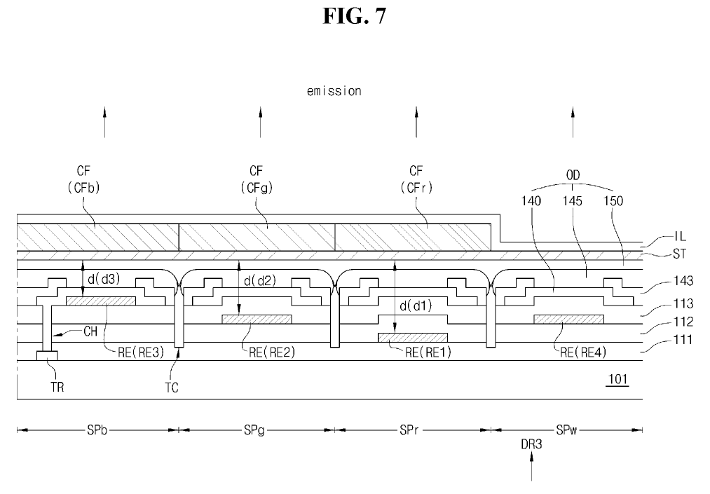

FIG. 7 is a cross-sectional view schematically illustrating a light emitting display device according to another embodiment of the invention.

In the following description, detailed explanations of components identical to or similar to those of an embodiment described above may be omitted.

Similar to the previously described embodiment in the light emitting display device according to another embodiment of the invention, the second electrode 150 may be formed as a transparent electrode, the semi-transmissive plate ST on the second electrode 150 may be formed over the entire substrate 101, and the insulating layer IL on the semi-transmissive plate ST may be formed on the upper surface of the semi-transmissive plate ST in the white subpixel SPw.

Meanwhile, unlike the previously described embodiment, in this embodiment, a fourth reflective plate RE4 positioned below the light emitting diode OD of the white subpixel SPw may be formed at the same location (or on the same plane) as the second reflective plate RE2 of the green subpixel SPg.

In other words, the fourth reflective plate RE4 of the white subpixel SPw may be formed simultaneously with the second reflective plate RE2 of the green subpixel SPg during the process of forming the second reflective plate RE2, and the fourth reflective plate RE4 may be positioned on the second passivation layer 112.

Even if the fourth reflective plate RE4 is formed in this manner, as mentioned in the previously described embodiment, the white subpixel SPw may have a non-micro-cavity structure due to the stacked structure of the second electrode 150/semi-transmissive plate ST/insulating layer IL, so that the transmissive characteristics of the white light of the white subpixel SPw may be stably secured.

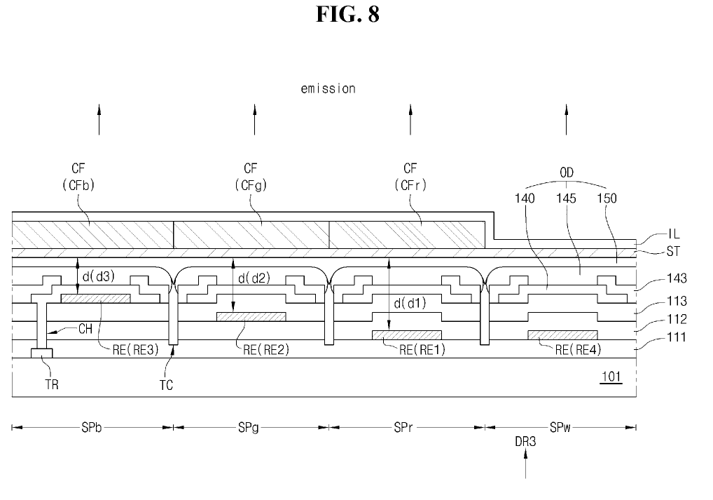

FIG. 8 is a cross-sectional view schematically illustrating a light emitting display device according to still another embodiment of the invention.

In the following description, detailed explanations of components identical or similar to those of the first and second embodiments described above may be omitted.

Similar to the previously described embodiments, in the light emitting display device according to still another embodiment of the invention, the second electrode 150 may be formed as a transparent electrode, the semi-transmissive plate ST on the second electrode 150 may be formed over the entire substrate 101, and the insulating layer IL on the semi-transmissive plate ST may be formed on the upper surface of the semi-transmissive plate ST in the white subpixel SPw.

Meanwhile, unlike the previously described embodiments, in this embodiment, a fourth reflective plate RE4 positioned below the light emitting diode OD of the white subpixel SPw may be formed at the same location (or on the same layer) as the first reflective plate RE1 of the red subpixel SPr.

In other words, the fourth reflective plate RE4 of the white subpixel SPw may be formed simultaneously with the first reflective plate RE1 of the red subpixel SPr during the process of forming the first reflective plate RE1, and the fourth reflective plate RE4 may be positioned on the first passivation layer 111.

Even if the fourth reflective plate RE4 is formed in this manner, as mentioned in the previously described embodiment above, the white subpixel SPw may have a non-micro-cavity structure due to the stacked structure of the second electrode 150/semi-transmissive plate ST/insulating layer IL, so that the transmissive characteristics of the white light of the white subpixel SPw may be stably secured.

As described above, according to embodiments of the invention, the semi-transmissive plate may be formed on the second electrode in not only the red, green, and blue subpixels but also in the white subpixel, and the insulating layer may be stacked on the semi-transmissive plate in the white subpixel.

Accordingly, the red, green, and blue subpixels may be configured with the micro-cavity structures that implement their corresponding color light, and the white subpixel may be configured with the non-micro-cavity structure that substantially transmits and outputs white light.

Therefore, the semi-transmissive plate may be formed across the entire subpixels without a separate process for removing the semi-transmissive plate from the white subpixel. Thus, the manufacturing process may be simplified while effectively implementing the white subpixel, thereby improving the overall emission efficiency of the light emitting display device.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A light emitting display device, comprising:
a substrate comprising a plurality of subpixels including red, green, blue, and white subpixels;
a light emitting diode provided in each of the plurality of subpixels and including a first electrode, a light emitting layer, and a second electrode stacked in a thickness direction, the second electrode including a transparent conductive material;
a semi-transmissive plate disposed on the light emitting diodes of the red, green, blue, and white subpixels; and
an insulating layer disposed on the semi-transmissive plate of the white subpixel.

2. The light emitting display device of claim 1, wherein the second electrode has a thickness in a range of about 10 nm to about 65 nm, the semi-transmissive plate has a thickness in a range of about 10 nm to about 30 nm, and the insulating layer has a thickness in a range of about 35 nm to about 80 nm.

3. The light emitting display device of claim 1, wherein the semi-transmissive plate comprises Ag or AgMg.

4. The light emitting display device of claim 3, wherein the second electrode comprises a transparent oxide conductive material.

5. The light emitting display device of claim 3, wherein the insulating layer comprises a transparent oxide insulating material or a transparent nitride insulating material.

6. The light emitting display device of claim 5, wherein the insulating layer comprises Al₂O₃.

7. The light emitting display device of claim 1, wherein the light emitting diodes of the red, green, blue, and white subpixels are each configured to emit white light,
wherein first, second, third, and fourth reflective plates are disposed below the light emitting diodes of the red, green, blue, and white subpixels, respectively,
wherein the first reflective plate is disposed below the second reflective plate, and
wherein the second reflective plate is disposed below the third reflective plate.

8. The light emitting display device of claim 7, wherein the fourth reflective plate is disposed on a same layer as one of the first, second, and third reflective plates.

9. The light emitting display device of claim 1, further comprising red, green, and blue color filter patterns disposed on the semi-transmissive plate in the red, green, and blue subpixels, respectively,
wherein the insulating layer overlaps the red, green, and blue color filter patterns.

10. A light emitting display device, comprising:
a substrate comprising a plurality of subpixels including red, green, blue, and white subpixels;
a light emitting diode provided in each of the plurality of subpixels and including a first electrode, a light emitting layer, and a second electrode which are stacked in a thickness direction, the second electrode being transparent;
a semi-transmissive plate disposed on the second electrode; and
a dielectric layer disposed on the semi-transmissive plate of the white subpixel.

11. The light emitting display device of claim 10, wherein the second electrode has a thickness in a range of about 10 nm to about 65 nm, the semi-transmissive plate has a thickness in a range of about 10 nm to about 30 nm, and the dielectric layer has a thickness in a range of about 35 nm to about 80 nm.

12. The light emitting display device of claim 10, wherein the semi-transmissive plate comprises Ag or AgMg,
wherein the second electrode comprises a transparent oxide conductive material, and wherein the dielectric layer comprises a transparent oxide insulating material or transparent nitride insulating material.

13. A light emitting display device, comprising:
a substrate including a plurality of subpixels which include red, green, blue, and white subpixels;
a light emitting diode provided in each of the plurality of subpixels and including a first electrode, a light emitting layer, and a second electrode stacked in a thickness direction, the second electrode including a transparent conductive material;
a semi-transmissive plate disposed on light emitting diodes of the red, green, blue, and white subpixels;
an insulating layer disposed on the semi-transmissive plate; and
a first reflective electrode disposed in the red subpixel, a second reflective electrode disposed in the green subpixel, a third reflective electrode disposed in the blue subpixel, and a fourth reflective electrode disposed in the white subpixel.

14. The light emitting display device of claim 13, wherein the first reflective electrode is disposed on a same layer as the fourth reflective electrode.

15. The light emitting display device of claim 13, wherein the second reflective electrode is disposed on a same layer as the fourth reflective electrode.

16. The light emitting display device of claim 13, wherein the third reflective electrode is disposed on a same layer as the fourth reflective electrode.

17. The light emitting display device of claim 13, wherein:
a distance from the third reflective electrode to the semi-transmissive plate is greater than a distance from the second reflective electrode to the semi-transmissive plate;
a distance from the second reflective electrode to the semi-transmissive plate is greater than a distance from the first reflective electrode to the semi-transmissive plate; and
a distance from the third reflective electrode to the semi-transmissive plate is greater than
a distance from the first reflective electrode to the semi-transmissive plate.
